(19) United States
(12) Patent Application Publication
(10) Pub. No.: US 2014/0103377 A1
(43) Pub. Date: Apr. 17, 2014

(54) OPTOELECTRONIC COMPONENT AND METHOD FOR ITS MANUFACTURING

(71) Applicant: Gertrud Kräuter, Regensburg (DE)

(72) Inventor: Gertrud Kräuter, Regensburg (DE)

(73) Assignee: OSRAM OPTO SEMICONDUCTORS GMBH, Regensburg (DE)

(21) Appl. No.: 13/635,843

(22) PCT Filed: Mar. 7, 2011
(86) PCT No.: PCT/EP2011/053381

§ 371 Date: Dec. 3, 2012

(30) Foreign Application Priority Data
Mar. 19, 2010 (DE) 10 2010 012 039.1

(51) Int. Cl. H01L 33/60; H01L 33/56

(52) U.S. Cl. CPC H01L 33/60; H01L 33/56
USPC 257/98; 438/26

(57) ABSTRACT

An optoelectronic component, including a housing including a thermosetting plastic including at least one material selected from the group consisting of aminoplastic thermosetting plastic, urea thermosetting plastic, melamine-formaldehyde thermosetting plastic, wet polyester thermosetting plastics, bulk molding compounds, polyester resin, phenolic resin and vinyl ester resin, a recess in the housing, and a radiation-emitting component, arranged in the recess, wherein the optoelectronic component includes a gate mark.

### RELATED APPLICATIONS

This is a §371 of International Application No. PCT/EP2011/053381, with an international filing date of Mar. 7, 2011 (WO 2011/113720 A3, published Sep. 22, 2011), which claims priority from German Patent Application No. 10 2010 012 039.1 filed Mar. 19, 2010, whose disclosure content is hereby included by reference.

### TECHNICAL FIELD

This disclosure relates to an optoelectronic component and a method of making the optoelectronic component.

### BACKGROUND

A widespread problem with optoelectronic components is that of finding a material which meets specific requirements and at the same time can still be readily processed.

It could therefore be helpful to find both a suitable material and a suitable method such that the component has the desired resistance and the material can nevertheless be readily processed.

### SUMMARY

I provide an optoelectronic component, including a housing including a thermosetting plastic including at least one material selected from the group consisting of aminoplastic thermosetting plastic, urea thermosetting plastic, melamine-formaldehyde thermosetting plastic, wet polyester thermosetting plastics, bulk molding compounds, polyester resin, phenolic resin and vinyl ester resin, a recess in the housing, and a radiation-emitting component, arranged in the recess, wherein the optoelectronic component includes a gate mark.

I also provide a method of manufacturing an optoelectronic component including molding a housing including a thermosetting plastic including a material selected from the group consisting of aminoplastic thermosetting plastic, urea thermosetting plastic, melamine-formaldehyde thermosetting plastic, wet polyester thermosetting plastics, polyester resin, phenolic resin and vinyl ester resin, and having a recess, by injection molding or transfer molding, curing the thermosetting plastic, detaching the projection which is present as a result of the injection molding or transfer molding process such that a gate mark is formed, and introducing the radiation-emitting component into the recess.

I further provide an optoelectronic component including a housing including a thermosetting plastic including a material selected from the group consisting of aminoplastic thermosetting plastic, urea thermosetting plastic, melamine-formaldehyde thermosetting plastic, wet polyester thermosetting plastics, bulk molding compounds and polyester resin, a recess in the housing, and a radiation-emitting component arranged in the recess, wherein the optoelectronic component includes a gate mark.

### BRIEF DESCRIPTION OF DRAWINGS

FIG. 1 shows a schematic cross section through a first example of the optoelectronic component.

FIG. 2 shows a schematic cross section through a second example of the optoelectronic component.

### DETAILED DESCRIPTION

I provide an optoelectronic component comprising
a housing comprising a thermosetting plastic,
a recess in the housing,
a radiation-emitting component arranged in the recess,
wherein the thermosetting plastic comprises a material selected from aminoplastic thermosetting plastic, urea thermosetting plastic, melamine-formaldehyde thermosetting plastic, wet polyester thermosetting plastics, bulk molding compounds (BMC), polyester resin, phenolic resin, vinyl ester resin, and
wherein the optoelectronic component comprises a gate mark.

Because the housing comprises one of the above-listed thermosetting plastics, it has significant advantages compared to a housing molded from thermoplastics. A thermosetting plastic, which by its nature, unlike a thermoplastic, has crosslinks such that a three-dimensional network is formed, exhibits markedly better chemical and physical resistance. Thus, for example, the thermosetting plastic displays greater heat and radiation resistance and greater mechanical stability. The greater surface hardness thus protects the housing of the optoelectronic component from mechanical damage.

The improved thermal stability makes it possible on the one hand for higher temperatures to be used in the process of manufacturing the optoelectronic component itself and also in subsequent method steps, in which for example, the optoelectronic component is attached to other components. The increased radiation resistance proves advantageous above all when the radiation-emitting component emits a wavelength range which also comprises a UV fraction.

Resistance relative, for example, to the radiation which is emitted by the radiation-emitting component reduces the aging phenomenon in particular of the region of the housing directly exposed to irradiation. Due to the greater stability relative to this radiation, the service life of the housing and this of the entire optoelectronic component may increase. Through the use of thermosetting plastics, the chemical resistance of the housing is also increased, which includes, for example, also increased resistance to solvents. Thus, in the manufacture of the housing, for example, or of the optoelectronic component, a greater number of possible solvents may be used.

One problem with thermosetting plastics has hitherto been that it is only with difficulty that they can be processed using an injection molding or transfer molding method.

This problem is solved by the above-listed thermosetting plastics. The thermosetting plastics specified here may be readily processed in an injection molding or transfer molding method if the method parameters are suitably selected. If a housing is manufactured with such a method, during manufacture it has a projection at the point at which the material from which the housing was made was injected into the mold. The projection is detached from the housing during the manufacturing process, wherein a gate mark is formed on the housing.

The gate mark is that point at which the projection was previously joined to the housing. This gate mark is a feature characteristic of the fact that the housing was produced using an injection molding or transfer molding method. The gate mark may, for example, be a small projection or but also a corresponding structure of the surface, which has arisen on the surface of the housing as a result of the process of detaching the projection. The gate mark makes it possible to determine even from the finished optoelectronic component that the latter was produced by an injection molding or transfer molding method.

The injection molding method allows large numbers of very good quality items to be produced inexpensively.

In the case of transfer molding, the thermosetting plastic may be injected by pistons from, for example, a heated antechamber via runners into the mold, in which it then cures under heat and pressure. When using thermosetting plastics this method offers the advantage that the transport paths of the thermosetting plastics are short and curing can be prevented prior to injection into the tool. With the transfer molding method the pressure preferably amounts to 50 to 500 bar.

The thermosetting plastic may comprise a material selected from: urea-formaldehyde resin, melamine-formaldehyde resin, unsaturated polyester (UP).

These three resins have proven particularly advantageous. They both exhibit very good heat and radiation stability and may nevertheless both be very readily processed by injection molding or transfer molding. Moreover, these resins have the advantage that they may be colored white. This is then particularly advantageous if a sub-region of the housing is formed as a reflector. Thus, for example, the inside of the reflector, which faces the radiation-emitting component, may be colored white. The coloring may increase the reflectivity of this part of the housing, which leads to a higher light yield of the optoelectronic component. The three resins listed additionally exhibit very good stability against irradiation, which also includes irradiation with UV light. Thus, the resins are also suitable for the manufacture of optoelectronic components which comprise radiation-emitting components which emit a wavelength range also comprising a UV fraction.

Furthermore, melamine resin-based thermosetting plastics and unsaturated polyesters exhibit very good rigidity and surface hardness. This gives the housing particularly good resistance against mechanical influences on the housing. Through this, it is possible to reduce mechanical damage and deformation at the surface of the housing, which may inter alia increase the service life of the housing.

The thermosetting plastic may comprise an aminoplastic. Aminoplastics exhibit particularly good flow behavior, for which reason they are particularly well suited for use in injection molding methods. In this way it is possible, for example, to operate with lower pressures during the production process than is necessary with other thermosetting plastics.

The thermosetting plastic additionally may comprise fibers as filler. The fibers may, for example, be glass fibers, but also cellulose fibers. Through the addition of these fibers to the thermosetting plastics the mechanical properties of the housing are improved in particular. The stability of the housing against tensile and shear stresses may be markedly increased by the fibers. The fibers may be adapted in terms of length to the particular requirements.

The thermosetting plastic may additionally comprise as filler a material selected from: mineral filler, titanium dioxide.

The titanium dioxide may be used, for example, to color the housing or sub-regions of the housing. As a result of the coloring, the reflectivity and radiation resistance of the housing may, for example, be increased.

By adding mineral fillers to the thermosetting plastic, the heat resistance thereof may, for example, be increased. However, increased mechanical and/or electrical strength may also be achieved such as improved current leak resistance. The mineral filler may, for example, be added in the form of powder or flakes.

The mineral filler may, for example, be wollastonite, a fibrous mineral filler. This improves the mechanical properties of the thermosetting plastic. It may, for example, also be chalk, CaCO₃, which improves surface integrity and mechanical properties.

The thermosetting plastic may additionally comprise as filler a material which reflects the radiation emitted by the radiation-emitting component.

Because the thermosetting plastic comprises such a material, the reflectivity relative to the radiation, which is emitted by the radiation-emitting component, may be increased. In this way, the light yield of the optoelectronic component may be increased. At the same time, the fraction of the radiation which penetrates into the housing is reduced, thereby reducing damage caused by the radiation. The filler may here be directly matched to the wavelength range which is emitted by the radiation-emitting component.

The radiation-emitting component may be an LED. The optoelectronic component may also have more than one recess in the housing, and thus also a plurality of LEDs, which may each be arranged in one recess. A plurality of LEDs may also be arranged in the same recess.

The radiation-emitting component may be an organic LED or OLED.

The housing may be molded from the thermosetting plastic. This should be understood to mean that the entire housing was made from at least one of the thermosetting plastics listed: aminoplastic thermosetting plastic, urea thermosetting plastic, melamine-formaldehyde thermosetting plastic, wet polyester thermosetting plastics, polyester resin, phenolic resin, vinyl ester resin.

In this case, the housing possesses, in particular, no fractions of thermoplastics and also no fractions of thermosetting plastics which are not listed above.

The housing may comprise precisely one of the above-listed thermosetting plastics.

In addition to the optoelectronic component, a method is also claimed for its manufacturing.

A variant for the manufacturing of an optoelectronic component, as described above, comprises the method steps:
molding a housing comprising a thermosetting plastic, and having a recess, by injection molding or transfer molding as method step A),
curing the thermosetting plastic as method step B),
detaching the projection which is present as a result of the injection molding or transfer molding process, such that the gate mark is formed, as method step C),
introducing the radiation-emitting component into the recess as method step D),
wherein in method step A) a thermosetting plastic is used which comprises a material selected from: aminoplastic thermosetting plastic, urea thermosetting plastic, melamine-formaldehyde thermosetting plastic, wet polyester thermosetting plastics, polyester resin, phenolic resin, vinyl ester resin.

By suitable selection of the thermosetting plastics for the housing, it is possible to mold the latter by injection molding or transfer molding. In this way, the housing has a projection which is detached in method step C) such that a gate mark is formed. With this gate mark, it is still possible to determine from the finished component that the housing of the optoelectronic component was produced by injection molding or transfer molding.

In a further variant of the method, the temperature of the cylinder of the feeding device is controlled during the injection molding or transfer molding.

In the case of injection molding and transfer molding of thermosetting plastics, control of the temperature during the process is advantageous so that the thermosetting plastic does not crosslink and thus cure in the feeding device as early as during the injection or casting process. This can result in clogging of the apparatus, bringing the process to a standstill. Here, the optimum temperature or the optimum temperature range needs to he matched to the thermosetting plastic used.

The cylinder may be controlled at a temperature of 60° C. to 80° C. A temperature within this temperature range is suitable for most of the stated thermosetting plastics. This ensures that curing of the thermosetting plastic does not occur as early as in the cylinder.

In method step A), molding may proceed by injection molding. Injection molding allows large numbers of very good quality items to be produced inexpensively.

The method step A) may be carried out at a pressure of greater than 1000 bar.

In injection molding, the pressure is preferably 1000 to 1500 bar. In addition to temperature, pressure constitutes a further important method parameter. By way of the pressure, for example, it is ensured that the injection material is pressed through the apparatus with a sufficient speed. This also contributes to prevention of early curing of the injection material in the apparatus. Furthermore, the pressure also ensures that the mold into which the material for the housing is injected is also filled completely with the material, without any external or internal recesses.

Moreover, the pressure also ensures that the injection process proceeds with sufficient speed. This on the one hand in turn ensures that early curing of the thermosetting plastic during the injection process does not occur, while on the other hand it allows a plurality of housings to be manufactured in a short period.

The mold in which the thermosetting plastic cures in method step B) may be held at a temperature of 150° C. to 250° C. during curing.

This temperature range is suitable for most of the thermosetting plastics listed above. In the injection molding and transfer molding methods, temperature control of the mold is advantageous specifically if thermosetting plastics are used. Since, in contrast to thermoplastics, thermosetting plastics have a three-dimensional, crosslinked structure, it is important that crosslinking proceeds uniformly and evenly throughout the housing, such that it can be ensured that the housing exhibits uniform stability. If, for example, two sub-regions of the housing exhibit a very high degree of crosslinking and the region located between these two sub-regions to exhibit only a very low degree of crosslinking, cracks in the housing could very easily occur in the region having the low degree of crosslinking. For this, it is important, for example, that the entire mold is firstly filled with the material for the housing before the crosslinking process is terminated in a sub-region of the housing. The crosslinking rate and the degree of crosslinking may thus be controlled inter alia by the temperature of the mold. The exact temperature may here be adjusted to the thermosetting plastic used, and also to the desired degree of crosslinking.

Crosslinking of the thermosetting plastic may take place during curing in method step B).

As already explained, crosslinking is significantly responsible for characteristic properties of the thermosetting plastic such as, for example, its stability against radiation and high temperatures. Due to crosslinking, the thermosetting plastic differs significantly from other groups of substances such as, for example, thermoplastics, which are, in general not crosslinked. The good heat resistance of the thermosetting plastic makes it possible, for example, for the housing, which is made from a material comprising such a thermosetting plastic, also to be subjected to higher temperatures without the housing being damaged or changing color. This may be of benefit, for example, in a soldering process. For instance, the housing may be joined to another component by a soldering process.

An LED may be used as the radiation-emitting component in method step D). It is also possible to use an organic LED or OLED.

Alternative forms of the components and methods are explained in greater detail below with reference to the figures and examples.

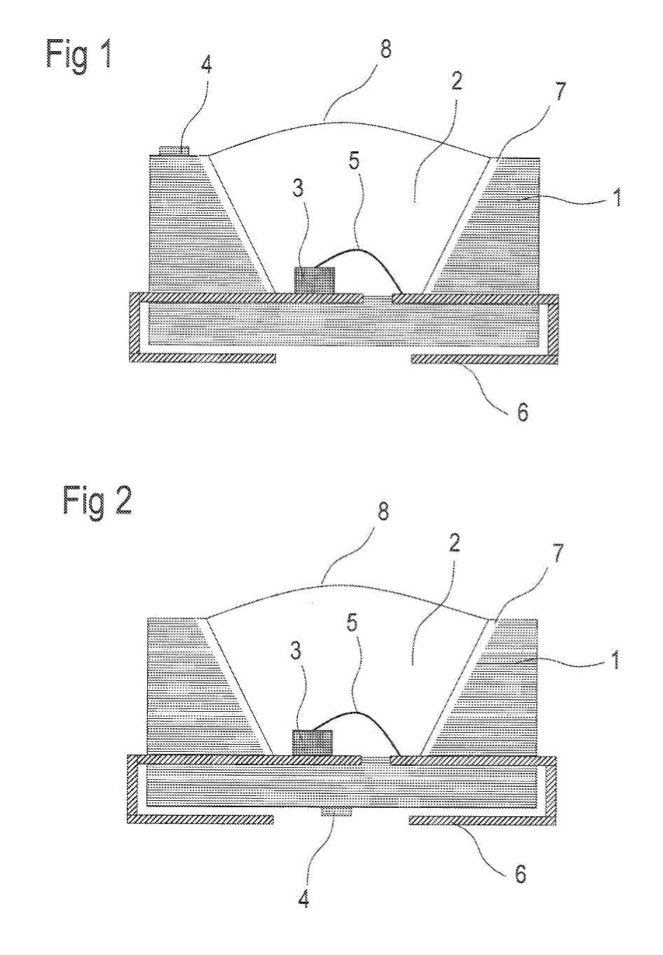

Turning now to the figures, FIG. 1 shows an optoelectronic component in schematic cross section. This comprises a housing 1, which comprises one of the above-stated thermosetting plastics. In the illustrated example, the entire housing 1 is molded from the thermosetting plastic. Thus, the physical and chemical properties of the housing are determined by the thermosetting plastic. In this way, the housing 1 has a very high resistance against heat, irradiation and also mechanical damage. The housing 1 comprises a recess 2 in which is arranged the radiation-emitting component 3. The radiation-emitting component 3 is connected both mechanically and electrically conductively to the first part of the lead frame 6. The radiation-emitting component 3 is additionally connected electrically conductively to the second part of the lead frame 6 via the bonding wire 5. The inner surface of the housing 1 facing the recess 2 is formed as a reflector 7. The reflector 7 displays greater reflectivity for the radiation emitted by the radiation-emitting component 3 than the rest of the housing 1. The recess 2 is filled with a casting compound formed at the radiation exit face in the form of a lens 8. The housing 1 can in particular be non-transmissive to the radiation emitted by the component 3.

The casting compound located in the recess 2 of the housing 1 is not regarded as a constituent of the housing, but rather merely as a constituent of the optoelectronic component overall.

The example illustrated in FIG. 1 has a gate mark 4 at its top face. In this example, the gate mark 4 takes the form of a small projection remnant. This gate mark 4 is a feature characteristic of the fact that the housing 1 was molded using an injection molding or transfer molding method. By gate mark 4, the finished optoelectronic component can still be clearly identified as having been produced using an injection molding or transfer molding method. From the position of the gate mark 4, it can be indentified that the injection or transfer mold was filled from the top with the material. The gate mark 4 was formed by detaching the projection.

FIG. 2 shows an example which largely corresponds to the example as shown in FIG. 1. However, the example shown in FIG. 2 comprises a gate mark 4 located at the bottom of the housing 1. This indicates that the housing 1 was produced upside down. In practice, the mold was arranged upside down to be filled from what is later the bottom side of the housing 1 with the material which forms the housing 1. Here too, the gate mark 4 has again been formed by detachment of the projection.

The gate mark 4 may also be situated at other points of the housing 1 than those shown in FIGS. 1 or 2. Moreover, the gate mark 4 may also have a form different than that shown in these two examples. For instance, the gate mark 4 may also be a structuring of the surface of the housing 1, which may result, for example, from subsequent grinding away of the still projecting material. It may, for example, also take the form of a deformation resulting from subsequent thermal treatment of that region at which projecting material remained on the housing, the projecting material was subsequently melted off.

Our components and methods are not restricted to the examples by the description on the basis of the examples. Rather, the disclosure encompasses any new feature and also any combination of features which in particular comprises any combination of features in the appended claims and any combination of features in the examples, even if those features or the combination itself is not explicitly specified in the claims or examples.

1.-15. (canceled)

16. An optoelectronic component comprising:
a housing comprising a thermosetting plastic comprising at least one material selected from the group consisting of aminoplastic thermosetting plastic, urea thermosetting plastic, melamine-formaldehyde thermosetting plastic, wet polyester thermosetting plastics, bulk molding compounds, polyester resin, phenolic resin and vinyl ester resin,
a recess in the housing, and
a radiation-emitting component arranged in the recess,
wherein the optoelectronic component comprises a gate mark.

17. The optoelectronic component according to claim 16, wherein the thermosetting plastic comprises at least material selected from the group consisting of urea formaldehyde resin, melamine-formaldehyde resin, unsaturated polyester resins.

18. The optoelectronic component according to claim 16, wherein the thermosetting plastic comprises an aminoplastic.

19. The optoelectronic component according to claim 16, wherein the thermosetting plastic further comprises fibers as filler.

20. The optoelectronic component according to claim 16, wherein the thermosetting plastic further comprises as filler at least one material selected from the group consisting of mineral fillers and titanium dioxide.

21. The optoelectronic component according to claim 16, wherein the thermosetting plastic further comprises as filler a material which reflects radiation emitted by the radiation-emitting component.

22. The optoelectronic component according to claim 16, wherein the radiation-emitting component is an LED.

23. The optoelectronic component according to claim 16, wherein the housing is molded from the thermosetting plastic.

24. A method of manufacturing an optoelectronic component according to claim 16 comprising:
A) molding a housing comprising a thermosetting plastic comprising a material selected from the group consisting of aminoplastic thermosetting plastic, urea thermosetting plastic, melamine-formaldehyde thermosetting plastic, wet polyester thermosetting plastics, polyester resin, phenolic resin and vinyl ester resin, and having a recess, by injection molding or transfer molding,
B) curing the thermosetting plastic,
C) detaching a projection present as a result of the injection molding or transfer molding process such that a gate mark is formed, and
D) introducing the radiation-emitting component into the recess.

25. The method according, to claim 24, wherein temperature of a cylinder of a feeding device is controlled during the injection molding or transfer molding.

26. The method according to claim 25, wherein temperature of the cylinder is controlled at 60° C. to 80° C.

27. The method according to claim 24, wherein (A) the molding proceeds by the injection molding method.

28. The method according to claim 27, wherein (A) is carried out at a pressure of greater than 1000 bar.

29. The method according to claim 24, wherein a mold in which the thermosetting plastic cures in (B) is held at a temperature of 150° C. to 250° C. during curing.

30. The method according to claim 24, wherein crosslinking of the thermosetting plastic takes place during curing in (B).

31. An optoelectronic component comprising:
a housing comprising a thermosetting plastic comprising a material selected from the group consisting of aminoplastic thermosetting plastic, urea thermosetting plastic, melamine-formaldehyde thermosetting plastic, wet polyester thermosetting plastics, bulk molding compounds and polyester resin,
a recess in the housing, and
a radiation-emitting component arranged in the recess,
wherein the optoelectronic component comprises a gate mark.
